(19) United States
(12) Patent Application Publication
(10) Pub. No.: US 2026/0303078 A1
(43) Pub. Date: Oct. 1, 2026

(54) MULTICHANNEL DRIVERS

(71) Applicant: Cirrus Logic International Semiconductor Ltd., Edinburgh (GB)

(72) Inventors: John P. LESSO, Edinburgh (GB); John L. MELANSON, Austin, TX (US)

(73) Assignee: Cirrus Logic International Semiconductor Ltd., Edinburgh (GB)

(21) Appl. No.: 19/092,158

(22) Filed: Mar. 27, 2025

(51) Int. Cl. H03K 17/00; H03F 3/21; H03F 3/213; H03F 3/217

(52) U.S. Cl. CPC H03K 17/002; H03F 3/211; H03F 3/213; H03F 3/217; H03F 2200/03

(57) ABSTRACT

This application relates to methods and apparatus for a multichannel driver, for driving each of a plurality of channels with a respective differential drive signal. The driver has a primary amplifier, which may preferably be a switching amplifier, for outputting a first output signal based a common drive signal component for each of said plurality of channels. The driver also has a respective secondary amplifier for each channel, which may be a linear amplifier. Each secondary amplifier outputs a respective second output signal based on an individual drive signal component for the respective channel, where a difference between the common drive signal component and the individual drive signal component for the respective channel corresponds to the differential drive signal for that channel.

### TECHNICAL FIELD

The field of representative embodiments of this disclosure relates to methods, apparatus and/or implementations concerning or relating to multichannel drivers, i.e. to drivers for driving two or more loads, such as output transducers, with respective driving signals, e.g. for stereo or multichannel audio.

### BACKGROUND

In audio applications, it is common for there to be a requirement to drive multichannel audio, i.e. to drive separate audio output transducers with respective drive signals. For example, for stereo audio, there is a need to drive separate loudspeakers with left channel and right channel audio signals. A multichannel audio driver will generally have a separate amplifier arrangement for each channel, for outputting a respective drive signal for that channel.

Switching amplifiers (or switched-mode amplifiers), such as class-D amplifiers, are used in a variety of applications and can have advantages in terms of power efficiency compared to linear amplifiers. In addition, for some relatively high-power applications, it may be challenging to provide a linear amplifier that has a desired linearity over the required output range, without a high feedback gain which can result in stability issues. Implementing a switching amplifier to meet a desired performance standard may thus be more straightforward for some use cases.

Switching amplifiers generally comprise an output stage for modulating at least one output node between defined switching voltages with a duty-cycle such that the average voltage at the output node, over the course of one or more switching cycles, has the desired level. Often, switching amplifiers may be configured to drive a load in a bridge-tied-load (BTL) configuration, and thus the load will be connected, in use, between first and second output nodes, each of which is modulated between selected switching voltages so as to generate a differential drive signal across the load.

In at least some applications, in particular for relatively high-power applications and/or in applications where there may be a relatively long output path between the output stage and the load, such as automotive or home theatre applications, there may be an output filter in the output path for filtering applying filtering to the output of the switching amplifier. For a BTL configuration, there will be an output filter in the output path on each side of the load. Such output filters may typically be implemented as an inductance-capacitance (LC) filter, with a series inductance in the output path and a shunt capacitance to a defined voltage, such as ground, and in some examples at least some of the components of the output filter, such as the series inductance, may be provided by components that are not integrated with the output stage, i.e. by external or off-chip components.

The use of switching amplifiers for multichannel drivers can thus require the presence of multiple components which are external or off-chip from the output stage. For instance, a stereo driver implemented with two BTL switching amplifier arrangements could require four external inductors, which can add to the size and cost of the driver and, in general, there is a desire to minimise size and cost.

In addition, whilst switching drivers can be relatively power efficient, the presence of the output filters can lead to increased power losses due to inductor core losses.

### SUMMARY

Embodiments of the present disclosure relate to methods and apparatus for multi-channel drivers that at least mitigate at least some of above-mentioned issues.

According to an aspect of the disclosure there is provided a multichannel driver for driving a load in each of a plurality of channels with a respective differential drive signal. The multichannel driver comprises a primary amplifier configured to output a first output signal at a first output node based a common drive signal component for each of said plurality of channels. The multichannel driver also comprises a plurality of secondary amplifiers, wherein the plurality of secondary amplifiers comprises a respective secondary amplifier for each channel of the plurality of channels, each secondary amplifier configured to output a respective second output signal at a respective second output node based on an individual drive signal component for the respective channel, where a difference between the common drive signal component and the individual drive signal component for the respective channel corresponds to the differential drive signal for that channel.

In some examples, the multichannel driver may further comprise a signal processor configured to receive a respective input signal for each of the plurality of channels and to generate the common drive signal component and the individual drive signal component for each of the plurality of secondary amplifiers. The signal processor may be configured to process the respective input signal for each of the plurality of channels so that all the input signals have a signal content within a first frequency band. The first frequency band may comprise a frequency range of a signal band for the input signals which is below a first frequency limit.

In some examples, the plurality of channels may comprise first and second channels and the common drive signal component may correspond to a common-mode component of the input signals for the first and second channels. The individual drive signal component for the first channel may correspond to a differential component of the input signals for the first and second channels and the individual drive signal component for the second channel may be the inverse of the individual drive signal component for the first channel. The input signals for the first and second channels may, in some cases, be left and right stereo audio input signals.

In some examples, the primary amplifier may be a switching amplifier. The switching amplifier may comprisea a switching stage configured to selectively modulate the first output node between a high-side switching voltage and a low-side switching voltage. In some implementations, the switching amplifier may comprise a switching stage configured to selectively modulate the first output node between selected voltages of a set of at least three switching voltages. The switching amplifier may comprise a class-D amplifier.

In some examples, each respective secondary amplifier may comprise a linear amplifier. Each of the linear amplifiers may comprise a class-AB amplifier. In some implementations, a power supply voltage for each of the linear amplifiers may be dynamically varied in use based on an indication of signal level of one or more of the individual drive signal components.

In some implementations, the load for each channel may be an audio output transducer.

An aspect also relates to a multichannel transducer apparatus comprising the multichannel driver of any of the embodiments described herein and a respective load transducer for each of said channels, wherein a first side of each of the load transducers is connected to a common node coupled to the first output node and a second of each of the load transducers is connected to a respective second output node. The common node may be connected to the first output node via a filter comprising a series inductance.

In another aspect, there is provided a multichannel driver for driving each of a plurality of loads in a respective plurality of channels with a respective differential drive signal based on a respective input signal. The multichannel driver comprises a linear amplifier for each channel configured to output an individual drive signal component for the respective channel and one switching amplifier for the plurality of channels. The switching amplifier is configured to output a common drive signal component for said plurality of channels, such that, for each of the channels, a difference between the individual drive signal component for the respective channel and the common drive signal component corresponds to the differential drive signal for that channel.

In a further aspect, there is provided a multichannel driver for driving a load in each of a plurality of channels with a respective differential drive signal, comprising a linear amplifier and a switching amplifier for each channel. The multichannel driver is selectively operable in a first mode of a second mode. In the first mode, each of the linear amplifier and switching amplifier for each channel is enabled, with the linear amplifier being configured to output a first differential drive component for driving one side of the relevant load and the switching amplifier being configured to output a second differential driver component for driving the other side of the relevant load, such that a difference between the first and second differential component corresponds to the differential drive signal for that channel. In the second mode, each linear amplifier for each channel is enabled and configured to output a first individual drive component for driving one side of the relevant load and one of the switching amplifiers for one of the channels is enabled and configured to output a common drive signal component for driving the other side of each of the loads for each of said plurality of channels.

In some examples, in the second mode, other than said one switching amplifier which is enabled, the rest of the switching amplifiers are disabled. The mode of operation may be controlled by a processor of multichannel driver.

It should be noted that, unless expressly indicated to the contrary herein or otherwise clearly incompatible, then any feature described herein may be implemented in combination with any one or more other described features.

### BRIEF DESCRIPTION OF DRAWINGS

For a better understanding of examples of the present disclosure, and to show more clearly how the examples may be carried into effect, reference will now be made, by way of example only, to the following drawings in which:

FIG. 1 illustrates one example of a conventional multichannel driver implemented using switching amplifiers

FIG. 2 illustrates an example of a multichannel driver according to an embodiment;

FIG. 3 illustrates a sample of left and right stereo audio data and the common-mode and differential components;

FIG. 4 illustrates another example of a multichannel driver according to an embodiment; and

FIG. 5 illustrates a further example of a multichannel driver.

### DESCRIPTION OF EMBODIMENTS

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

Embodiments of the disclosure relate to multichannel drivers, i.e. drivers for driving at least two different loads, e.g. output transducers, with respective drive signals, which include a switching amplifier. Embodiments relate, in particular, to multichannel audio driver but are not limited to audio applications.

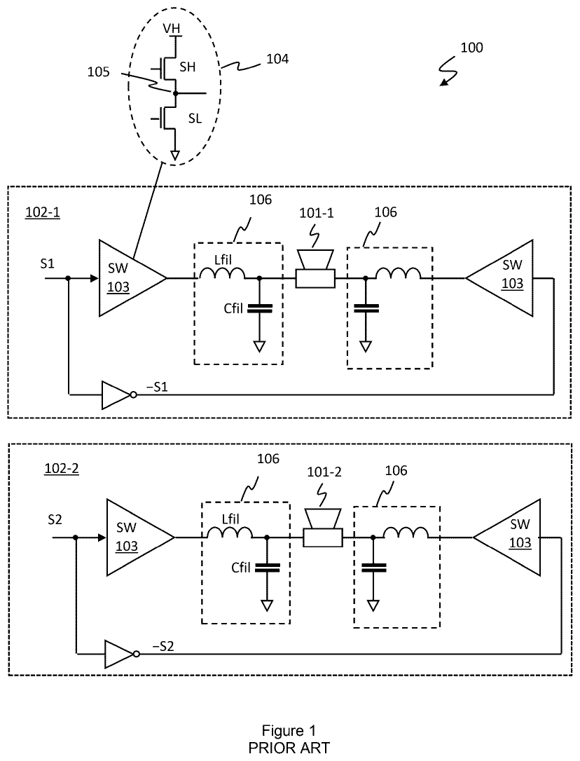

FIG. 1 illustrates one example of how a conventional multichannel driver 100 may be implemented using switching amplifiers. FIG. 1 illustrate an example of a two-channel driver for driving first and second loads 101-1 and 102-1, which in this example are audio output transducers but it will be understood that multichannel driver may be used to drive a variety of different loads. First and second channel drivers 102-1 and 102-2 are provided for separately driving the first and second loads 102-1 and 102-2 respectively. Each of the first and second channel drivers 102-1 and 102-2 comprises a switching amplifier arrangement for driving the load in a bridge-tied-load (BTL) configuration. This is illustrated in FIG. 1 by showing a respective switching amplifier 103 on each side of the load, where each switching amplifier 103 may be implemented as a class-D amplifier comprises a switching stage 104 for modulating an output node 105 of the switching amplifier 103 between different switching voltages. FIG. 1 illustrates one example of a possible switching stage 104, which comprises a high-side switch SH for selectively connecting the output node 105 to a high-side voltage VH and a low-side switch for selectively connecting the output node 105 to a low-side voltage, which is ground in this example. It will be understood that this is just one example, however, and other arrangements of switching stage are possible, and, in some cases, a multilevel switching amplifier could be used in which the switching voltages for modulating the output node could be selected from a set of at least three different switching voltages, e.g. a high-side voltage, a low-side voltage and at least one intermediate voltage. Note, as used herein, the terms high-side and low-side, in relation to switching voltages, shall be taken as meaning that the high-side voltage is more positive/less negative than the low-side voltages and nothing is meant or implied about any magnitude of the relevant switching voltages.

FIG. 1 illustrates that, for the first channel driver 102-1, a signal S1 is used as the input for a switching amplifier on one side of the load 101-1 and an inverted version is used the input for the switching amplifier on the other side of the load 101-1. For an AD-type modulation scheme the signal S1 may be a PWM signal used for controlling switching of the switching stage 104, where the PWM signal is derived from an input signal Sin1 for that channel, e.g. by a suitable upstream modulator (not separately illustrated). For a BD-type modulation scheme the signal S1 could be the input signal Sin1 and each of the class-D amplifier may comprise a suitable modulator (not illustrated) for generating PWM control signals for controlling switching of the switching stage 104.

The second channel driver 102-2 has the same general structure as the first channel driver 102-1.

The example of FIG. 1 also illustrates that there is an output filter 106 in the output path between each switching amplifier 103 the relevant load 101-1 or 101-2. As will be understood by one skilled in the art, for some applications, some filtering in the output path may be important, for instance for relatively high-power applications, e.g. for driving an output power of 10W or greater, and/or where the output path between the switching amplifiers 103 and the relevant load may be relatively long, e.g. of the order of tens of centimetres or greater. For example, audio systems in automotive applications and home theatre and the like may typically be required to output relatively high output powers and may have output paths of the order of tens of centimetres to meters between the switching amplifiers and the loudspeaker being driven. In such applications, filtering of the output path may be important. Typically, each output filter 106 may comprise an LC (inductance-capacitance) filter which is separate to the relevant load. FIG. 1 illustrates one example of a basic filter 106 with a series inductance Lfil in the output path and capacitance Cfil between the output path and a defined reference voltage, such as ground, on each side of the load. Other LC filter arrangements may be implemented, however, as would be understood be one skilled in the art. Where the switching stages 104 of the multichannel driver 100 are implemented as an integrated circuit, the respective output filters 106 may be implemented, at least partly by external components, i.e. components which are off chip and not part of that integrated circuit. For example, at least the inductor Lfil of each output filter 106 may be implemented as an external, i.e. off-chip, component. For the two-channel driver 100 illustrated in FIG. 1, this would require four external inductors, and for a greater number of channels, there would be need for an extra two external inductors per additional channel. The need for a relatively high number of external inductors can add to the size and/or cost of the multichannel driver and generally a small size and/or low cost is desirable.

In addition, whilst switching amplifiers can generally be more power efficient that a linear amplifier, such as a class-AB amplifier or the like, one source of power losses in a switching amplifier used with an output filter is inductor losses. The inductor losses, as will be understood by one skilled in the art, can have a dependence on the ripple current in the inductor due to modulation of the voltages at the relevant output node for that output filter. The inductor ripple current has a dependence on duty-cycle and for a switching stage such as illustrated in FIG. 1 for modulating the output node between a high-side voltage and a low-side voltage, a quiescent signal level may correspond to a duty-cycle of 50%, with a relatively high ripple current.

To reduce the number of inductors required, at least some embodiments of the present disclosure use one switching amplifier to provide a drive signal component for multiple different loads.

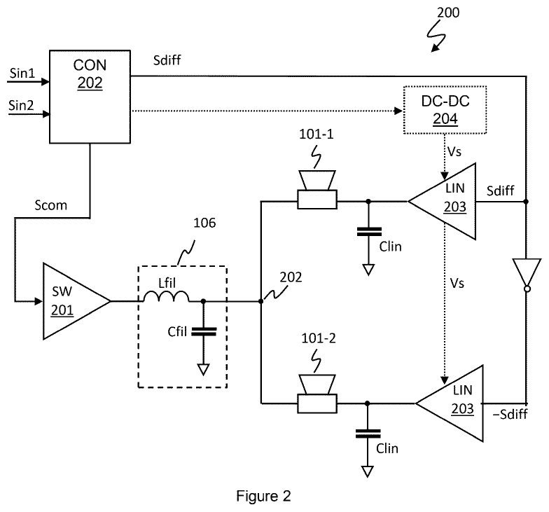

FIG. 2 illustrates one example of a multichannel driver 200 according to embodiment, in which similar components as discussed with reference to FIG. 1 are identified by the same reference numerals. FIG. 2 illustrates an example of a two-channel driver for driving first and second loads 101-1 and 101-2, which are illustrated as loudspeakers in this example, but embodiments also relate to driving of other loads.

FIG. 2 illustrates that the multichannel driver 200 comprises a primary switching amplifier, in this example a switching amplifier 103. The switching amplifier 103 may be implemented as any type of switching amplifier and may, for example, comprise a class-D amplifier. The switching amplifier 103 may comprise a switching stage such as illustrated in FIG. 1, e.g. a half-bridge state, with switches for selectively connecting the output of the switching amplifier to either of two switching voltages, or may, in some embodiments, be a multi-level switching amplifier that can selectively modulate the output between selected voltages from a set or three of more possible switching voltages. The output of the switching amplifier 103 is connected to an output filter 106, in a similar manner as discussed above. FIG. 2 illustrates that the output filter comprises a series inductor Lfil and, in this example, a shunt capacitance Cfil but other filter arrangements could be implemented. As discussed above, at least the filter inductance Lfil could be implemented by an external or off-chip component, i.e. not formed as part of an integrated circuit with the switching stage of the switching amplifier 103.

In the embodiment of FIG. 2, the output from the switching amplifier 103, after filtering, is used as a drive signal component for both of the first and second loads 101-1 and 101-2. Thus, a first side of each of the first and second loads 101-1 and 101-2 is connected to a common drive node 201, where the common drive node 201 receives the filtered output of the switching amplifier 103, i.e. the output filter 106 is connected in an output path between the switching amplifier 103 and the common drive node 201.

The input for the switching amplifier 103 is a signal Scom from a signal processor 202, which, in this example, represents a common drive signal component for the first and second channels. The signal processor 202 thus receives input signals Sin1 and Sin2 for the first and second channels respectively and, in one example, determines the common drive signal component Scom as:

$$Scom = ( Sin 1 + Sin 2 ) / 2 \qquad Eqn . ( 1 )$$

The common drive signal component Scom could thus be seen as a common-mode component of the input signals for the different channels.

To provide the correct differential drive signal across the load for each channel, the second side of each of the first and second loads 101-1 and 101-2 is driven, by a respective secondary amplifier, with a respective individual drive signal component that results in the correct differential drive signal across the load. In the example of FIG. 2, the second side of the second load 101-2 is driven with a signal Sdiff, where:

$$Sdiff = ( Sin 1 - Sin 2 ) / 2 \qquad Eqn . ( 2 )$$

The signal Sdiff can be seen as the differential component of the input signals for the first and second channels.

The differential drive signal across the second load transducer 101-2 will thus be:

$$Scom - Sdiff = ( Sin 1 + Sin 2 ) / 2 - ( Sin 1 - Sin 2 ) / 2 = Sin 2$$

The second side of the first load 101-1 is driven with an individual drive signal component that corresponds to −Sdiff and thus the differential drive signal across the first load transducer 101-1 is:

$$Scom - Sdiff = ( Sin 1 + Sin 2 ) / 2 + ( Sin 1 - Sin 2 ) / 2 = Sin 1$$

The signal processor may thus determine the drive signal components Scom and Sdiff based on the received input signals Sin1 and Sin2, and the signal Sdiff can be inverted to provide −Sdiff—although it will be understood that the signal processor could instead determine −Sdiff which could be inverted to provide Sdiff, or the signal processor could determine both Sdiff and −Sdiff itself. It will be understood, however, that whilst determining Scom and Sdiff (and/or −Sdiff) in this way is convenient in terms of minimising processing, in some implementations the common drive signal component could be determined as some other combination of the first and second input signals Sin1 and Sin2, with appropriate modifications to the respective individual drive signal components applied to the second side of the first and second load transducers 101-1 and 101-2.

Whilst the second side of the first and second loads 101-1 and 101-2 could be driven with these drive individual signal components, e.g. −Sdiff and Sdiff, using switching amplifiers as the secondary amplifiers, such switching amplifiers would generally require the presence of output filters, with an associated inductor. In the embodiment of FIG. 2, the individual drive signal components are applied using respective linear amplifiers 203, for example class-AB amplifiers. Linear amplifiers, as will be understood by one skilled in the art, produce an analogue output signal which varies with the input to the linear amplifier and thus the output of linear amplifiers do not require the same filtering as the output of the switching amplifier.

In applications such as multichannel audio, for instance stereo audio, the audio content of the different channels may exhibit a relatively substantial degree of correlation. For instance, for stereo audio, there is generally a relatively substantial degree of correlation between the left and right audio channels, particularly for lower frequencies. Differences between the left and right audio channels tend to be in the higher frequency content, which generally is lower amplitude. In other words, a common-mode component of typical stereo audio may be relatively high and contain most of the audio power, whereas a differential component of stereo audio may comprise a relatively low power signal.

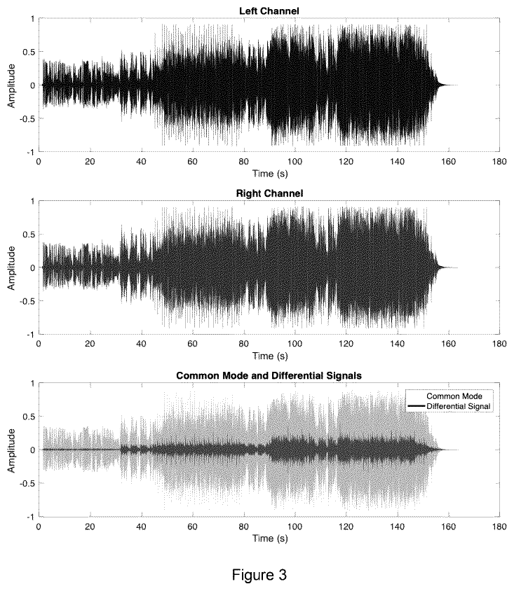

FIG. 3 illustrates this principle. FIG. 2 illustrates a sample of representative stereo audio, and the top and middle waveforms show the signal level over time for the left channel and right channel audio respectively, on a normalised scale of −1 to +1 where +1 is a maximum positive signal level and −1 is a maximum negative signal level. In this example, the amplitude of both the left and right audio channels is initially relatively low but which then increases to near full-scale. The lower plot shows the common-mode and differential components of the left and right audio, i.e. the values of Scom and Sdiff determined according to equations 1 and 2. It can be seen there is a significant common-mode component which largely tracks with signal amplitude, but the differential component has a much smaller amplitude and, in this example, even for near full-scale left/right channel audio the amplitude of the differential component remains relatively low.

Referring back to FIG. 2, given the output range which is expected for the individual drive signal components, i.e. for Sdif and −Sdiff may thus be relatively low, the amplifiers for driving these individual drive signal components can be implemented as linear amplifiers, such as class-AB amplifiers, as linear amplifiers may be implemented which provide acceptable performance over this relatively limited range. The use of linear amplifiers 203 to drive the individual drive components for the different channels means that inductors are not required as part of an output filter in an output path between the relevant linear amplifier 203 and the relevant load 101-1 or 101-2. There may, as illustrated in FIG. 2, be an output capacitance Clin at the output of each linear amplifier, which in some cases could be an external capacitance, but in some implementations could be integrated with the switching stage. The two channel driver 200 of FIG. 2 thus requires only one filter inductor Lfil, compared to the four filter inductors for the conventional approach illustrated in FIG. 1.

The linear amplifiers 203, used for applying the individual drive signal components to the second side of the first and second load 101-1 and 101-2, may, in at least some implementations, be less power efficient than a corresponding switching amplifier may be, but this may be at least partly mitigated by the fact that there are no inductor losses arising from a filter inductor in the output path from the linear amplifier to the load. In some implementations, the linear amplifiers may be implemented as class-G or class-H type amplifiers, where a power supply voltage to the amplifier may be varied based on an indication of the signal output required from the linear amplifier 203, so as to minimise power losses when possible whilst still providing sufficient headroom for the required output from the linear amplifier 203. The signal processor 202 could, for example, control a DC-DC converter 204 to output a suitable supply voltage Vs for the linear amplifiers 203 based on an envelope or peak signal level of the Sdiff drive signal component.

As noted above, the embodiment illustrated in FIG. 2 is advantageous for implementations where the signal content of the different input signals for the different channels is expected to have a relatively substantial degree of correlation and, in some applications, this will typically be for the lower frequency content. In some applications the signal processor 202 may be configured, in at least some modes of operation, to mix the signal content of the different input signals within a first frequency band into a combined signal for the first frequency band which can then be applied to all channels. In other words, the signal processor 202 may modify the input signals such that the modified input signals all have the same signal content in the first frequency band. For an application to stereo audio, the stereo audio input signals may effectively be mixed to a mono signal within the first frequency band, which may be the lower frequency part of the audio band (as for low frequencies, a listener may not perceive much stereo difference, even if present). The modified input signals can then be processed to provide the common drive signal component Scom and the differential signal component Sdiff. This operation may result in a greater amount of audio power in the common drive signal component Scom and thus reduce the power output required for the linear amplifiers 203.

In the event that the input signals Sin1 and Sin2 that are received are substantially uncorrelated, there may not be much signal content in the common drive signal component, and thus the common drive signal component may be a near quiescent signal, e.g. around zero. In this case, substantially all of the signal swing for the respective drive signal for the respective channels will be delivered by the linear amplifiers 203, which may limit the maximum signal output that can be produced. However, in some applications such substantially uncorrelated input signals may be exceptional and may unlikely to have an amplitude at or near full-scale, so this operation in the unlikely use case may be tolerated.

The embodiment of FIG. 2 may thus be intended for an application where the signals in the different channels are expected to be substantially correlated in normal operation. It may, however, be useful for a given multichannel driver circuit to be operable in the manner as described above with respect to the FIG. 2 when used for correlated channels but also to be operable as a multichannel driver for driving different channels that may be substantially uncorrelated. This can allow, for example, the same type of multichannel driver to be implemented in different use cases, e.g. used by manufacturers of different devices.

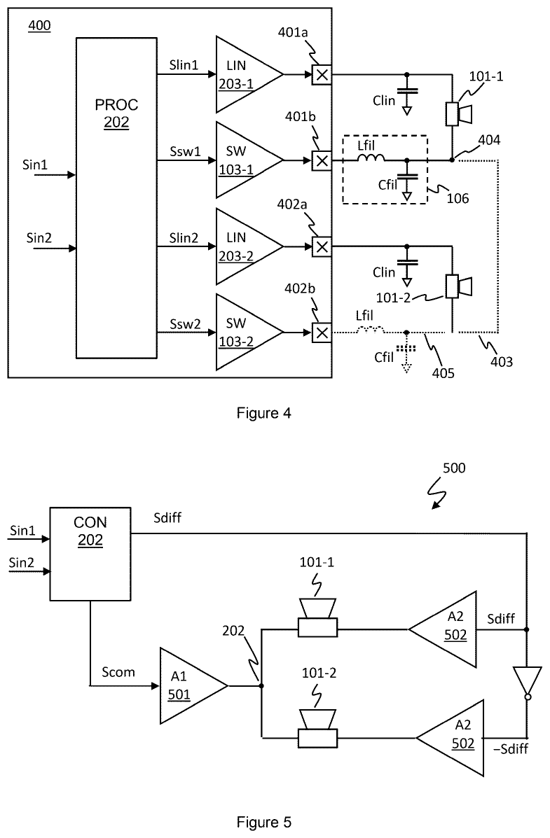

FIG. 4 illustrates one example of a multichannel driver 400 according to an embodiment which can be operated to in different modes to drive different channels which may be, at least partly correlated, or which may be substantially uncorrelated. Again, similar components as discussed previous in relation to FIGS. 1 and 2 are identified by the same reference numerals. FIG. 4 illustrates an example of a two-channel driver for driving first and second loads 101-1 and 101-2 with appropriate differential drive signals based on respective first and second input signals Sin1 and Sin2.

The multichannel driver 400 comprises a first amplifier pair comprising a first linear amplifier 203-1 and a first switching amplifier 103-1, with their outputs connected to respective output terminals 401a and 401b of a first pair of output terminals. The multichannel driver 400 also comprises a second amplifier pair comprising a second linear amplifier 203-2 and a second switching amplifier 103-2 with their outputs connected to a respective output terminals 402a and 402b of a second pair of output terminals.

In use, the first load 101-1 may be connected between the first pair of output terminals, such that one side the first load 101-1 is connected to the output terminal 401a at the output of the first linear amplifier 203-1, and the other side of the first load 101-1 may be connected, via an output filter 106, to the output terminal 402a at the output of the first switching amplifier 103-1.

For a use case where it is expected that the input signals Sin1 and Sin2 will exhibit a relatively substantial degree of correlation, e.g. for a stereo audio application, then one side of the second load 101-2 may be connected to the output terminal 402a at the output of the second linear amplifier 203-2, and the other side of the second load 101-2 may also be connected, to the output terminal 402a at the output of the first switching amplifier 103-1 via the output filter 106. This is illustrated by possible connection path 403. In this case node 404 on the load side of the output filter 106 may be considered to be a common node as discussed in relation to FIG. 2.

In this configuration, the output node 402b may be left floating or could, in some cases, be tied to some defined voltage such as ground. This configuration thus uses a single external filter inductor Lfil.

In operation for this use case, the signal processor 202 may be operated in a first mode in which the first switching amplifier 103-1 and first and second linear amplifiers 203-1 and 203-2 are driven with appropriate drive signal components as discussed with reference to FIG. 2. That is, a signal Ssw1 input to the first switching amplifier 103-1 may be equal to a common drive signal component Scom and the signals Slin1 and Slin2 input to the first and second linear amplifiers 203-1 and 203-2 respectively may be equal to −Sdiff and Sdiff respectively. In this first mode, the second switching amplifier 103-2 is not used, and may be unpowered.

For a use case where it is expected that the input signals Sin1 and Sin2 are, or may be, substantially uncorrelated, the first load 101-1 may be connected between the first pair of output terminals 401a and 401b in the same way. However, in this case, the second load 101-2 is connected between the second pair of output terminals 402a and 402b with the second load 101-2 being connected to the output terminal 402b at the output of the second witching amplifier 103-2 via a filter inductor Lfil, as indicated by possible path 405, and there is no connection between the first and second loads 101-1 and 101-2.

In operation for this use case, the signal processor 202 may be operated in a second mode in which each of the first and second loads 101-1 and 101-2 is driven by a respective amplifier pair comprising a switching amplifier on one side of the load and a linear amplifier on the other side of the load. For this second mode of operation, the signals Slin1 and Ssw1 supplied to the first linear amplifier 203-1 and the first switching amplifier Ssw1 will be based on the first input signal Sin1 only and are controlled to generate the correct differential drive signal across the load. In some embodiments, the signals Slin1 and Ssw1 could be equal to (Sin1)/2 and −(Sin1)/2 respectively, but in some cases there may be a greater gain applied to the signal Ssw1 supplied to the first switching amplifier 103-1 so as to increase the power from the first switching amplifier 103-1 compared to the first linear amplifier 203-1 and/or to reflect a greater output range for the switching amplifier compared to the linear amplifier. Thus, the signal Ssw1 could be equal to pSin1 and the signal Slin1 could be equal to −(p−1)Sin1, where p is greater than 0.5 and less than 1.

The relevant mode of operation in the first or second mode could be based on a suitable memory setting or the like, which may be set, for instance by the manufacturer of the host device as part of device assembly or may be determined by firmware loaded into the device, e.g. to the signal processor 202. In some examples, the connection status of the output terminals could be used to determine the configuration and hence a suitable operating mode.

The examples above have been described in relation to two different channels but it should be understood that the principles of using a switching amplifier to drive a common drive signal component could be applied to more than two different channels. For instance, some multichannel audio may have a reasonable degree of correlation between more than two different audio channels. For instance, consider N different channels for N different load transducers, with a respective input signal Sin1, Sin2 . . . SinN for each channel. One side of each of the N different load transducers could be connected to a common node which is driven by a switching amplifier with a common drive signal component equal to (Sin1+Sin2+. . . SinN)/N, i.e. equal to a common-mode component of all the input signal. The individual drive signal component for each channel is then difference between that common-mode component and the relevant input signal for that channel.

Referring back to FIG. 2, this embodiment shows an example where the primary amplifier, for driving multiple loads with the common drive signal component, is a switching amplifier 103, and the secondary amplifiers, for driving the respective loads with the relevant individual drive signal component, are linear amplifiers 203. This use of a switching amplifier 103 as the primary amplifier and linear amplifiers as the secondary amplifiers is particularly advantageous for the reasons set out above. However, the general principles could be applied to other combinations of different type of amplifier.

FIG. 5 illustrates generically an embodiment of a multichannel driver 500 according to an embodiment which has a primary amplifier 501 for outputting a drive signal based on a common drive component for two loads 101-1 and 101-2, and two secondary amplifiers 502, each secondary amplifier configured to drive one of the loads with a respective individual drive signal component. In some implementations, the primary amplifier 501 and each of the secondary amplifiers 502 could be implemented as switching amplifiers. This can provide advantages in terms of power efficiency but may require the presence of an output filter (not illustrated) for each of the switching amplifiers. Where the primary and secondary amplifiers 501 and 502 are switching amplifiers, each of the switching amplifiers (i. e, the primary amplifier 501 and each secondary amplifier 502) may be switched at the audio rate and, in some examples, the switching of the secondary amplifiers 502 may be coordinated with switching of the primary amplifier 501. In some implementations the secondary switching amplifier may be operated in a linear mode at zero-crossing of the relevant drive signal component so as to reduce distortion.

In some embodiments, however, each of the primary amplifier 501 and secondary amplifiers 502 may be implemented as a linear amplifier, e.g. a class-AB amplifier or the like. The primary amplifier 501 and/or each secondary amplifier 502 may be implemented to make use of class G or class H type techniques and may thus be provided with at least one power supply voltage that varies with signal level, in a similar manner as discussed above. Splitting the drive signal components in this way may ease the design constraints on the secondary amplifiers 502 as they may not be needed to provide such a large dynamic range as the primary amplifier 501 and/or each of the common drive signal component and individual drive signal component may allow for better optimization of the power supply voltages for the different amplifiers, with resultant benefits in terms of power efficiency.

Embodiments of the present disclosure thus relate to methods and apparatus for multichannel drives for driving different loads with respective differential drive signals. Embodiments are operable to drive a common node connected, in use, to at least two different loads with a common drive signal component output from a primary amplifier, which may, in some embodiments, be a switching amplifier, and to drive the other said of said at least two loads with individual drive signal components so as to generate the desired differential voltage across each of the loads. The individual drive signal components may be generated, in some embodiments, using respective linear amplifiers. Embodiments are particularly suitable for multichannel audio, but could be implemented for other multichannel drivers in cases where there would be expected to be at least some correlation between the input signals for the different channels.

Embodiments may be implemented in a host device, which could be a portable and/or battery powered host device such as a mobile computing device for example a laptop, notebook or tablet computer, or a mobile communication device such as a mobile telephone, for example a smartphone. The device could be a wearable device such as a smartwatch. The host device could be a games console, a remote-control device, a home automation controller or a domestic appliance, a toy, a machine such as a robot, an audio player, a video player. Embodiments may be implemented as part of a system provided in a home appliance or in a vehicle or interactive display. There is further provided a host device incorporating the above-described embodiments.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A multichannel driver for driving a load in each of a plurality of channels with a respective differential drive signal, comprising:
a primary amplifier configured to output a first output signal at a first output node based a common drive signal component for each of said plurality of channels;
a plurality of secondary amplifiers, wherein the plurality of secondary amplifiers comprises a respective secondary amplifier for each channel of the plurality of channels, each secondary amplifier configured to output a respective second output signal at a respective second output node based on an individual drive signal component for the respective channel;
wherein a difference between the common drive signal component and the individual drive signal component for the respective channel corresponds to the differential drive signal for that channel.

2. The multichannel driver of claim 1 further comprising a signal processor configured to receive a respective input signal for each of the plurality of channels and to generate said common drive signal component and said individual drive signal component for each of the plurality of secondary amplifiers.

3. The multichannel driver of claim 2 wherein the signal processor is configured to process the respective input signal for each of the plurality of channels so that all the input signals have a signal content within a first frequency band.

4. The multichannel driver of claim 3 wherein the first frequency band comprises a frequency range of a signal band for the input signals which is below a first frequency limit.

5. The multichannel driver of claim 1 wherein the plurality of channels comprises first and second channels and wherein the common drive signal component corresponds to a common-mode component of the input signals for the first and second channels, the individual drive signal component for the first channel corresponds to a differential component of the input signals for the first and second channels and the individual drive signal component for the second channel is the inverse of the individual drive signal component for the first channel.

6. The multichannel driver of claim 5 wherein the input signals for the first and second channels are left and right stereo audio input signals.

7. The multichannel driver of claim 1 wherein the primary amplifier is a switching amplifier.

8. The multichannel driver of claim 7 wherein the switching amplifier comprises a switching stage configured to selectively modulate the first output node between a high-side switching voltage and a low-side switching voltage.

9. The multichannel driver of claim 8 wherein the switching amplifier comprises a switching stage configured to selectively modulate the first output node between selected voltages of a set of at least three switching voltages.

10. The multichannel driver of claim 8 wherein the switching amplifier comprises a class-D amplifier.

11. The multichannel driver of claim 8 wherein each respective secondary amplifier comprises a linear amplifier.

12. The multichannel driver of claim 11 wherein each linear amplifier comprises a class-AB amplifier.

13. The multichannel driver of claim 11 wherein a power supply voltage for each of the linear amplifiers is dynamically varied in use based on an indication of signal level of one or more of the individual drive signal components.

14. The multichannel driver of claim 1 wherein the load for each channel is an audio output transducer.

15. A multichannel transducer apparatus comprising the multichannel driver of claim 1 and a respective load transducer for each of said channels, wherein a first side of each of the load transducers is connected to a common node coupled to the first output node and a second of each of the load transducers is connected to a respective second output node.

16. The multichannel transducer apparatus of claim 15 wherein the common node is connected to the first output node via a filter comprising a series inductance.

17. A multichannel driver for driving each of a plurality of loads in a respective plurality of channels with a respective differential drive signal based on a respective input signal, comprising:
a linear amplifier for each channel configured to output an individual drive signal component for the respective channel;
one switching amplifier for the plurality of channels, the switching amplifier being configured to output a common drive signal component for said plurality of channels;
such that, for each of the channels, a difference between the individual drive signal component for the respective channel and the common drive signal component corresponds to the differential drive signal for that channel.

18. A multichannel driver for driving a load in each of a plurality of channels with a respective differential drive signal, comprising:
a linear amplifier and a switching amplifier for each channel; and
the multichannel driver being selectively operable in a first mode of a second mode, wherein:
in the first mode, each of the linear amplifier and switching amplifier for each channel is enabled, with the linear amplifier being configured to output a first differential drive component for driving one side of the relevant load and the switching amplifier being configured to output a second differential driver component for driving the other side of the relevant load, such that a difference between the first and second differential component corresponds to the differential drive signal for that channel; and
in the second mode, each linear amplifier for each channel is enabled and configured to output a first individual drive component for driving one side of the relevant load and one of the switching amplifiers for one of the channels is enabled and configured to output a common drive signal component for driving the other side of each of the loads for each of said plurality of channels.

19. The multichannel driver of claim 18 wherein, in the second mode, other than said one switching amplifier which is enabled, the rest of the switching amplifiers are disabled.

20. The multichannel driver of claim 18 wherein the mode of operation is controlled by a processor of multichannel driver.
